(19) United States
(12) Patent Application Publication
(10) Pub. No.: US 2026/0277123 A1
(43) Pub. Date: Sep. 17, 2026

(54) METHOD FOR IMPROVING THE PREDICTION OF A CURRENT FOCUS STARTING POINT IN A SEMICONDUCTOR TECHNOLOGY APPARATUS

(71) Applicant: Carl Zeiss SMT GmbH, Oberkochen (DE)

(72) Inventors: Asad Rasool, Jena (DE); Susanne Toepfer, Baumersroda (DE); Klaus Gwosch, Aalen (DE); Ulrich Matejka, Jena (DE)

(21) Appl. No.: 19/553,640

(22) Filed: Mar. 2, 2026

(30) Foreign Application Priority Data
Mar. 17, 2025 (DE) 102025110196.5

(51) Int. Cl. G03F 9/00; G03F 1/84

(52) U.S. Cl. CPC G03F 9/7026; G03F 1/84

(57) ABSTRACT

Disclosed is a method for predicting a best focus for focusing at a current measurement location of at least one section of an object in a semiconductor technology apparatus and is distinguished by the fact that the current best focus is determined at least on the basis of focus starting point information from at least one previous measurement location in the vicinity of the current measurement location.

### CROSS REFERENCE TO RELATED APPLICATION

The present application claims the priority of the German patent application 10 2025 110 196.5 filed on Mar. 17, 2025, the content of which is fully incorporated by reference herein.

### TECHNICAL FIELD

The disclosure relates to a method for improving the prediction of a current focus starting point for focusing at a measurement location of at least one section of an object in a semiconductor technology apparatus, in particular a mask inspection microscope.

### BACKGROUND

In semiconductor technology, various processes are combined for producing microstructured components, such as integrated circuits or LCDs (liquid crystal displays). The processes include, inter alia, the production and qualification of objects in the form of photolithographic masks, which are also referred to as photomasks or simply masks, and the production of objects in the form of substrates, in particular wafers, and the qualification thereof. This usually involves measuring or registering sections with the structures or structure elements to be measured.

In the central so-called lithography process or microlithography process, the mask is illuminated in a projection exposure apparatus by an illumination unit. The light passing through the mask or the light reflected by the mask is projected, by means of a projection optical unit, onto a substrate (for example a wafer), which is coated with a light-sensitive layer (photoresist) and mounted in the image plane of the projection optical unit, in order to transfer the structure elements of the mask to the light-sensitive coating of the substrate. The structure transferred in this way to the substrate is formed in an electrically conductive material in a further process step. A microstructured component usually comprises between 20 and 50 of these layers, which cooperate to form a three-dimensional component. The process described above is thus repeated multiple times. An error, for example a structure positioning error, that is to say a displacement of the structure on the mask with respect to a position stipulated during design and/or a deviation in a critical dimension (CD) of a structure, can lead to the failure of the entire electrical component during production, which is why the masks and the wafers are checked for possible defects in inspection processes by means of so-called mask or wafer inspection apparatuses.

Structure elements must therefore be positioned very accurately on the surface of masks so that the permissible deviations from the predefined positions thereof or deviations from a critical dimension of a structure element are in the nanometre range, preferably in the sub-nanometre range, so as not to lead to errors on wafers during the exposure with the corresponding mask. The production of photomasks which can meet these requirements is extremely complex, susceptible to errors and hence expensive. Thus, damaged masks or masks with deviations from the desired specifications must be repaired whenever possible.

An important precondition for repairing defective masks is the finding and characterization of defects which are present, in particular of positioning errors and/or deviations of critical dimensions. The detection of positioning errors and/or deviations of critical dimensions is complicated and difficult but these variables need to be determined with an accuracy in the single-digit nanometre range, preferably in the sub-nanometre range.

Measuring devices, for example mask inspection microscopes, are used for the examination of positioning errors and/or the critical dimensions. An image of the mask structures that is as sharp as possible is a precondition for an accurate determination of positioning effects and/or deviations of the critical dimensions. This requires the surface of the mask to be positioned as accurately as possible in what is known as the focal plane of the imaging optical unit of the measuring device.

The focal plane is the location at which a flat object, for example the mask surface, must be positioned in order to be recorded in a recording device with maximum sharpness. In a z-direction that runs perpendicular to the mask surface, the location of this focal plane depends on the distance between the recording device and an imaging optical unit of the mask inspection microscope, and on the optical properties of the imaging optical unit. Thus, its location is defined by the configuration of the mask inspection microscope.

Despite being called focal plane, the focus of the imaging optical unit is not situated in said focal plane. Using terminology from geometrical optics, the focal plane in fact is a plane at the object distance which is assigned to a fixed image distance (determined by the properties and configuration of the imaging optical unit and the recording device). In this case, the maximum permissible deviation from the focal plane (target location) allowing capture of a sharp image of the mask surface is determined by the depth of focus (usually a few hundred nanometres) of the imaging optical unit. It is advantageous here to position an object to be examined in the region of the focal plane with an accuracy of down to a few nanometres where possible.

In order to determine the focal plane, the deviation of the position of a mask surface from the focal plane is determined during focusing in the measuring devices. Two types of focusing are known in the measuring devices, where one determines the best focus by means of autofocusing not explained here in more detail and the other determines the best focus by recording a so-called focus stack. The focus stack is a number of multiple images, usually five to nine images, which are recorded at different distances between the mask and the imaging optical unit and on the basis of which the z-position of the best focus is determined by means of an image evaluation carried out in evaluation electronics.

Both types of focusing have in common the fact that, at the start of focusing, the mask is positioned at a so-called focus stack starting point at which the focusing starts.

If a focus stack of seven images is recorded, the first focus stack starting point FSᵣ, as shown in FIG. 2, is at a distance of three times the step size between the individual images of the focus stack in the z-direction from the predicted best focus F_{bv} for the current measurement location.

$$F {S}_{r} = {F}_{bv} - ( {A}_{Ab} ⋆ ( {A}_{A} - 1 ) / 2 )$$

where
FSᵣ=focus stack starting point (z-position)
F_{bv}=predicted best focus (z-position)
A_{Ab}=distance between the images in the z-direction A_{A}=number of images.

In the case of insufficient accuracy of the predicted best focus F_{bv}, the maximum contrast Kₘ₀, which is determined by the evaluation of the recorded images and is shown in FIG. 2 as a dashed circle, is often far outside the centre of the focus stack. The maximum contrast Kₘ₀ corresponds to the best focus F_{b0} of the first measurement at the current measurement location, which is represented in FIG. 2 by a dashed line.

If the distance of the best focus F_{b0} of the first measurement, as in approximately 40% to 70% of the cases, is too far from the middle image, as shown in FIG. 2, a second focus stack with the images ABₓ is captured. The ideal focus stack starting point FSᵢ for the second focus stack is determined starting from the best focus F_{b0} of the first measurement using the formula above.

The best focus F_{b} of the second focus stack is then determined, again by determining the maximum contrast Kₘ by evaluating the images ABx recorded in the focus stack, and corresponds to the z-position of the focal plane of the measuring device used.

As shown in FIG. 2, the z-position of the best focus F_{b} corresponds in the fewest cases to the z-position of the middle image AB₄ of the focus stack. As a result of the repeated measurement based on the maximum contrast Kₘ₀ of the first measurement, the individual images ABₓ now result in an almost symmetrical curve of the contrast around the best focus F_{b}, which is represented in FIG. 2 by a solid line. The more closely the curve of the images ABₓ corresponds to perfect symmetry around the best focus F_{b}, the higher the accuracy of the best focus F_{b} determined.

In the prior art, the determination of the z-position, i.e. the predicted best focus F_{bv} for the current measurement location, as the basis for calculating the focus stack starting point FSᵣ, is composed of two components which are also referred to as static and dynamic components.

The static component ATₛ is the component that is determined before the actual measurement or registration of the mask. The measurement comprises predefined parameters, such as the thickness of the mask and/or the tilt of the mask in a recording of the measuring device when calibrating the measuring device. In addition, deviations of the mask surface from an ideal plane are also determined by simulation with the aid of FE models, such as a central sagging of the mask due to gravity. For each position to be approached for the measurement of a structure or for each measurement location, a static deviation from an ideal plane is thus known.

The dynamic component of the deviation is composed of inaccuracies or tolerances of the determined static components and of deviations of the mask and/or structure during operation that are dependent on environmental conditions, in particular temperature changes, and therefore cannot be determined in advance.

Due to the fact that the dynamic component cannot be determined in advance, a deviation A_{I} corresponding to the dynamic component is determined in the prior art, as shown in FIG. 3A, at the preceding measurement location ME_{I}. The deviation A_{I} corresponds to the difference between the prediction of the best focus BF_{IV} at the preceding measurement location ME_{I} and the best focus BF_{IM} measured subsequently at the preceding measurement location ME_{I}. For the purposes of this disclosure, a preceding measurement ME_{I} refers to a measurement ME_{I} carried out immediately before the current measurement MEₐ. The deviation A_{I} determined in this way is subsequently used as a correction value Kars or as a dynamic component for correcting the known static component BF_{asA} of the current measurement MEₐ. The static component BF_{asA} is shown using dashed lines in FIG. 3A in order to distinguish it from the measured best focus BF_{IM} of the preceding measurement ME_{I}. The term “current” for the purposes of this disclosure refers to all method steps for the measurement MEₐ that has just been carried out or is still pending.

FIG. 3A shows a three-dimensional diagram with the mask surface O_{Ms} determined in advance on the basis of the static deviations. The diagram shows the preceding measurement ME_{I} and the current measurement MEₐ.

The method has the disadvantage that the geometric distance between the current measurement and the preceding measurement can be comparatively large, as a result of which in particular the dynamic deviations, which can have a dependence on the geometric distance, such as the coating thickness of the structures, can lead to large deviations.

### SUMMARY

It is an object of the present disclosure to specify a method which eliminates the disadvantages of the prior art described further above.

In general, in one aspect, disclosed is a method for predicting a best focus for focusing at a current measurement location of at least one section of an object in a semiconductor technology apparatus. The method is distinguished by the fact that the current predicted best focus is determined at least on the basis of focus information from at least one previous measurement location in the vicinity of the current measurement location.

A vicinity for the purposes of th is disclosure is a spatially defined region or area.

The term “previous” refers to all measurements already carried out before the current measurement, i.e. not just the last measurement in time.

The section of an object, which can be, for example, a mask for semiconductor technology, is the portion of the mask in which the structure elements or structures of interest to be measured are located.

The semiconductor technology apparatus can be, for example, a mask inspection, mask registration, mask repair or wafer inspection apparatus or any other apparatus in which an object is to be focused or positioned at a predetermined measurement location.

For the purposes of this disclosure, focus information refers to any information used to determine the best focus. It can include the position to be approached that is determined on the basis of a measurement and/or simulation, in particular in the z-direction, that is to say the position of a mask plane ideal for imaging, which is also referred to as the focal plane, and the components referred to in the introduction as static and dynamic deviations.

In particular, for determining the at least one previous measurement location for determining the focus information to be taken into account, an area around the current measurement location can be defined. The area may have a circular, rectangular or basically any other shape.

Furthermore, it is possible to define a time period, which may be at most between the time of the at least one measurement at a previous measurement location (ME₁, ME₂) and the time of measurement at the current measurement location (MEₐ), so that the measurement at the previous measurement location (ME₁, ME₂) can be used to determine the focus information (Aᵥ₁, Av2) to be taken into account. This has the advantage that (an item of) focus information from measurements that are too far in the past and can have comparatively large deviations caused by drift effects compared to only recently performed measurements is not used to determine the current best focus.

The selection of the previous focus information can therefore be within the defined area and/or the defined time period. This means that both the local and the temporal distance between the previous measurement locations is taken into account.

In a further embodiment, a travel regime for approaching the measurement locations can be defined such that within the time period at least one measurement at a previous measurement location for determining the best focus based on focus information at the current measurement location is always within the defined area. For the purposes of this disclosure, the travel regime comprises the order in which the individual measurement locations on the object, such as a mask for semiconductor technology, are approached.

In particular, the focus information may include deviations between a best focus predicted for a previous measurement location and a best focus determined after focusing at the same measurement location. The deviation can correspond to a first approximation to the previously used dynamic deviation. According to the embodiments herein, it may also be advantageous to use the deviations of multiple previous measurements within the predefined area around the current measurement and optionally within a predefined time period as a basis for the deviation.

Furthermore, the current predicted best focus can be determined on the basis of predictable deviations and/or the focus information determined at previous measurement locations. On the one hand, the focus information can correspond to the deviation explained further above or the measured best focus.

In a further embodiment, a structure class can be determined for a structure element formed in the section to be measured.

For the purposes of this disclosure, a structure class refers to a class of structures in the production of microstructured components, such as integrated circuits or LCDs (liquid crystal displays). For example, structure classes can be contact holes, parallel lines, or crossed lines, i.e. crosses. The structure class influences different parameters in the measurement and imaging of structures, such as the polarization of the used light. In connection with registration of a structure, the structure class can influence the z-position of the focal plane of the structure to be measured in a registration apparatus.

A structure class offset can also be determined on the basis of the structure class. Each structure class has a specific z-offset with respect to an ideal image or measurement, which is referred to below as the structure class offset. The structure class offset also depends on the imaging optical unit and the illumination of the respective registration apparatus, that is to say it also has an apparatus dependency.

In particular, the structure class offset in the case of known structures can be determined on the basis of simulation models. In this case, the structure is first imaged with an assumed ideal imaging optical unit and illumination using a simulation. In a second step, the known illumination and imaging errors of the apparatus used are taken into account in the simulation, which allows the focal plane to shift in the z-direction. The difference between the two focal planes is the structure class offset which is specific to each structure class and apparatus.

The determination of the structure class, the structure class offset and/or the influence of the structure class offset on the determination of the current predicted best focus or the at least one item of focus information for the measurement at the current measurement location can also be supported and/or carried out by machine learning.

Furthermore, the current predicted best focus or the at least one item of focus information for the measurement at the current measurement location can be corrected with the structure class offset of the previous measurement location and the current measurement location. In the case of a different structure class between the current measurement location and the previous measurement location and an already known structure class offset, the following procedure can be performed:

The structure class offset of the structure (e.g. cross) of the previous measurement location is subtracted from the determined structure-dependent measured best focus of the previous measurement location. The structure-independent best focus obtained in this way is now adapted to the structure class of the current measurement location by adding the structure class offset known for the structure (e.g. contact hole) at the current measurement location. The predicted best focus obtained in this way corresponds almost to the value that would have been determined on the basis of identical structure classes between the previous measurement location and the current measurement location. Furthermore, when using focus information to determine the best predicted focus at the current measurement location, the structure class offset, as explained above, can also be used to correct the focus information.

In a further embodiment, the at least one item of focus information and the at least one best focus can be normalized with the structure class offset. For the purposes of this disclosure, normalization means a structural independence of the data used to determine the best focus at the current measurement location. This has the advantage that, even if multiple previous measurements are used to determine the best focus at the current measurement location, only the structure class of the structure at the current measurement location must be known. In other words, the structure class of the focus information used to determine the predicted focus at the current measurement location is no longer relevant. This has the additional advantage that more measurements at previous measurement locations can be used, since the known influence of the structure class can be eliminated by the normalization. The structure class offset is simply added to the value determined from the previous measurements. Normalization is also advantageous for the creation, explained below, of a focus information map or a focus map of the best focuses.

The explained structure class offset and the associated normalization of measurements or images for generating structure-independent values, as well as the consideration of structure classes when measuring, registering, simulating or emulating images of a structure in semiconductor technology, can be regarded as an independent aspect of this disclosure invention and can be regarded as novel and inventive even without the features of the method disclosed herein.

In a further embodiment, a focus information map and/or a focus map can be determined from the focus information from the previous measurements. A focus information map contains an area that is determined using a suitable interpolation based on the existing deviations of the previous measurements and includes a prediction of the correction value for the current static component of the current predicted best focus at the current measurement location. A focus map contains an area that is determined using a suitable interpolation based on the existing measured best focuses of previous measurements and includes the current predicted best focus at the current measurement location.

In particular, the focus information map or the focus map can be determined for the defined area. In this case, the focus information from all previous measurements will not be used to determine the focus information map or the focus map, but rather, for example, only the information determined according to the method explained above.

In a further embodiment, an interpolation method and/or a regression method and/or a machine learning method can be used to determine the focus information map or the focus map. The methods differ fundamentally in the mathematical methods used to determine the focus information map or the focus map.

In particular, a thin plate spline can be used to determine the focus information map or the focus map. Alternatively, one of the following methods can be used: Inverse distance weighted (IDW) method, modified Shepard method, ordinary or universal kriging, and other spline methods.

In addition, a least squares fit (LSQ fit) method can be used to determine the focus information map or the focus map. This can clearly determine a plane in x, y, z at three points. An LSQ fit for a curved surface element in x, y, z, where x may have a different curvature than y, can be determined with sufficient accuracy with at least six points.

In addition, a Bayesian model can be used to determine the focus information map or the focus map. A Bayesian model is a method that is used by machine learning and uses a probability distribution to determine new data points.

In another embodiment, the current predicted best focus can be determined on the basis of the focus information map. This has the advantage that the focus information for determining the best focus or the best focus does not need to be re-determined directly for every current measurement. The focus information or the current predicted best focus can be determined directly via the coordinate of the current measurement location from the existing focus information map (focus map) or an existing section of the focus information map (focus map). The method can therefore improve both the accuracy and the throughput time of the measurement of an object of a semiconductor technology apparatus.

In a further embodiment, the order in which the measurement locations are approached can be defined in such a way that the determination of the focus information map or the focus map is optimized in time and/or space. The order thus takes into account the distance from the previous measurements and can sometimes deviate greatly from the usually used meandering travel along the object formed as a mask. Instead of moving along the mask line by line, where there is a change to the next line in each case at the edge of the mask, the method according to certain embodiments will measure the mask starting from a starting point, comparable to the spreading of a liquid which hits a surface at a point. This ensures that a maximum number of the previous measurement locations are within the area, explained further above, around the current measurement location. This means that the focus information map or the focus map can be used earlier than the previous order explained, or measurement locations with a minimum distance can be taken into account.

Furthermore, the travel regime can use a base cell. A base cell comprises a predefined number of measurement locations.

In particular, the number of measurement locations in the base cell can be defined on the basis of the stability of the machine and/or the measurement environment. This can ensure that no measurement results from measurements that are too long ago and thus could have excessively large drift errors and could lead to an inaccurate prediction of the predicted focus are used to determine the focus information. The more stable the machine/machine environment, the larger the base cell can become. In the case of a very stable machine/machine environment, the base cell can also include the entire mask.

In a further embodiment, the base cell can be moved after approaching all the measurement locations belonging to the base cell. In this case, for the purposes of this disclosure, the approach implicitly comprises carrying out the measurements provided at the respective measurement location.

In particular, the base cell can be moved in such a way that the base cell always comprises a sufficient number of measurement locations for determining the focus information map or the focus map. The number may depend on the methods explained further above for determining the focus information map or the focus map.

In a further embodiment, the semiconductor technology apparatus can be in the form of a registration apparatus.

Other aspects, embodiments, and advantages may follow.

### DESCRIPTION OF DRAWINGS

Exemplary embodiments and variants will be explained in more detail below on the basis of the drawing, in which:

FIG. 1 shows a schematic illustration of a mask inspection microscope from the prior art which can be used to perform embodiments of the method disclosed herein,

FIG. 2 shows a diagram for explaining a method for determining a best focus,

FIGS. 3A and 3B show a diagram for explaining the method,

FIG. 4 shows a flowchart of the method,

FIG. 5 shows a diagram for explaining a detail of an embodiment, and

FIG. 6 shows a schematic illustration of a detail of the method.

### DETAILED DESCRIPTION

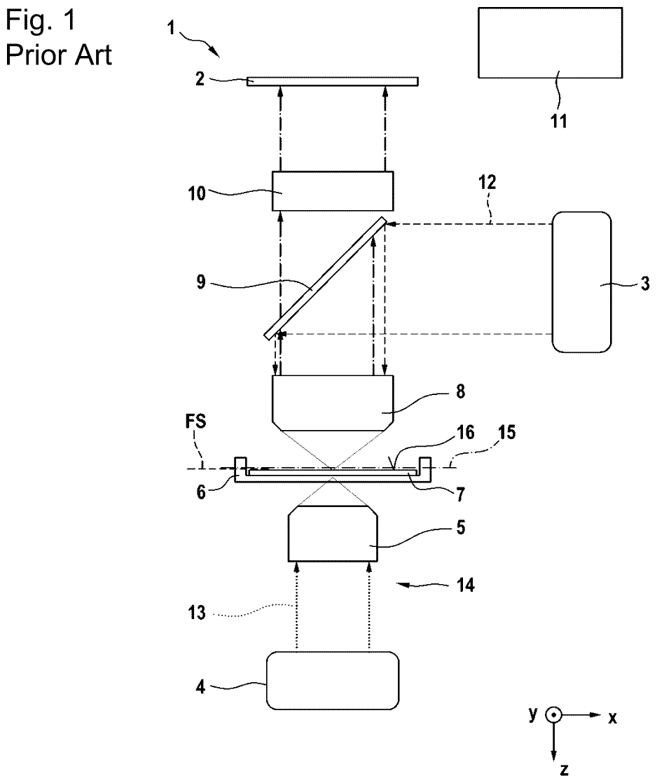

FIG. 1 shows a schematic illustration of a measuring device known from the prior art, which is designed as a mask inspection microscope 1 and serves to measure an object for semiconductor lithography in the form of a photomask or mask 7, in which the inventive method for improving the prediction of a current best focus can be used. The mask inspection microscope 1 comprises two light sources 3, 4, with a first light source 3 being designed to measure the mask 7 in reflection and a second light source 4 being designed to measure the mask 7 in transmission. The mask 7 is arranged on an object stage 6, which can position the mask 7 laterally (x-y-direction) and vertically (z-direction) in the sub-nanometre range. In this case, the positioning accuracy can be in a range of less than 500 μm in particular, more particularly less than 250 μm.

During a measurement in transmission, the measurement light 13 of the illumination unit 14 comprising the light source 4 and an illumination optical unit designed as a condenser 5 passes through the condenser 5, which generates a desired light distribution on the mask 7. Then, the measurement light 13 passes through the mask 7, a magnifying imaging optical unit 8 and a tube 10, and arrives at a recording device 2 in the form of a CCD camera in the example shown. The semi-transparent mirror 9 arranged between the imaging optical unit 8 and the tube 10 is used for the measurement in reflection and has no influence on the measurement in transmission.

During a measurement in reflection, the measurement light 12 emitted by the light source 3 is reflected at the semi-transparent mirror 9 and subsequently passes through the imaging optical unit 8, with the result that the mask surface 16 is illuminated. Then, as in the case of a measurement in transmission as well, the illuminated mask surface 16 is imaged in magnified fashion on the recording device 2 by way of the imaging optical unit 8.

The recording device 2, the object stage 6, the imaging optical unit 8 and the light sources 3, 4 are connected to a controller 11 which controls the interplay of the individual components 2, 3, 4, 6, 8 using an open-loop or closed-loop mechanism and which is also designed to process the captured images.

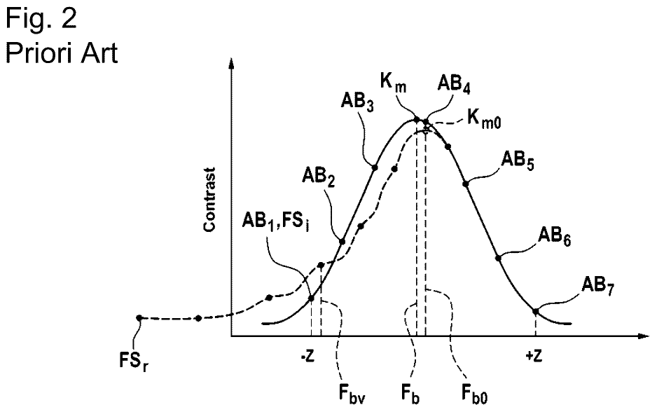

FIG. 1 furthermore illustrates the so-called focal plane 15. The focal plane 15 is the location at which a flat object such as the mask surface 16 must be positioned in order to be recorded with maximum sharpness on the recording device 2 and thus corresponds to the best focus F_{b} explained in FIG. 2. In the z-direction, the location of this focal plane 15 depends on the distance between the recording device 2 and the imaging optical unit 8, and on the optical properties of the imaging optical unit 8. Thus, its location is defined by the configuration of the mask inspection microscope 1. Despite being called focal plane, the focus of the imaging optical unit 8 is not situated in said focal plane. Using terminology from geometrical optics, the focal plane in fact is a plane at the object distance which is assigned to a fixed image distance (determined by the properties and configuration of the imaging optical unit 6 and the recording device 2).

In order to determine the focal plane, the deviation of the position of a mask surface from the focal plane is determined during focusing in the measuring devices. For this purpose, at the start of focusing, the mask is positioned at a so-called focus stack starting point FS at which the focusing starts. The starting point is independent of whether autofocusing or a focus stack is used to determine the focal plane or for the location of the sharpest recording, which is also referred to as the best focus, which is relevant to the subsequent evaluation of the image.

In the embodiment illustrated in FIG. 1, the mask surface 16 is located at a previously determined focus stack starting point FS, which is usually arranged slightly below the expected best focus. For example, a focus stack is recorded from this focus stack starting point FS and the best focus is determined on the basis of the individual images, as already explained further above.

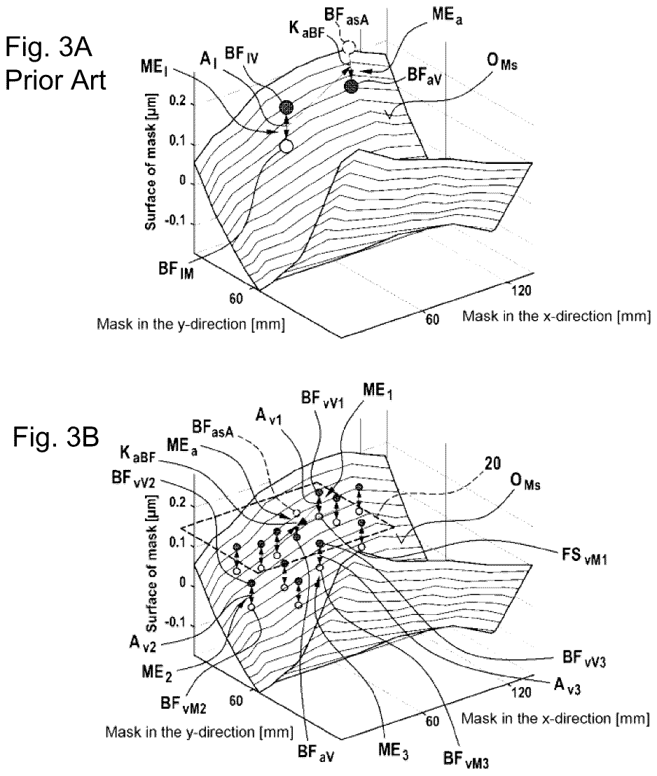

FIG. 3B shows a diagram for explaining an embodiment of the method for improving the prediction of a current best focus, from which the current focus stack starting point FS for focusing is determined. FIG. 3B shows a three-dimensional diagram with the mask surface O_{Ms} determined in advance on the basis of the static deviations.

FIG. 3B illustrates all the measurement locations ME₁, ME₂, ME₃, at which measurements have already been carried out, in an environment around the current measurement location MEₐ. For reasons of clarity, FIG. 3B has a reference sign only at three measurement locations ME₁, ME₂, ME₃. A predefined area 20 around the measurement location MEₐ, which is formed in the exemplary embodiment illustrated in FIG. 3B as a rectangle illustrated using dashed lines, serves to select the previous measurement locations ME₁, ME₂ of interest for the prediction of the current best focus BF_{aV}. The area 20 thus defines a region on the mask surface 16 (FIG. 1), i.e. in the x-y plane of the coordinate system spanned in FIG. 3B. In the exemplary embodiment shown, only the measurement locations ME₁, ME₂ whose predicted or measured best focus BF_{vV1}, BF_{vM1} BF_{vV2}, BF_{vM2} is within the area 20 are taken into account. For example, the previous measurement location ME₃ is not taken into account for this reason because it is not within the defined area 20. Therefore, the predicted BF_{vV3} and measured best focus BF_{vM3} are not taken into account either.

Another selection criterion is the time period between the current measurement MEₐ and the previous measurement locations ME₁, ME₂ from the local selection that are relevant to the determination of the current best focus BFₐᵥ. This second selection criterion ensures that fluctuations occurring, for example, due to drift effects in the machine do not have a negative influence on the determination of the correction value K_{aFS} or the best predicted focus BFₐᵥ of the current measurement MEₐ.

In order to determine the current best focus BFₐᵥ, the correction value Kars and the dynamic component of the current best focus BFₐᵥ are determined on the basis of all deviations Aᵥ₁, Aᵥ₂ of the measurements carried out at the measurement locations ME₁, ME₂ within the area 20. With the already previously determined static component BF_{asA} (FIG. 3A), this results in the current predicted best focus BFₐᵥ. The use of the deviations Aᵥ₁, Aᵥ₂ of the measurement locations ME₁, ME₂ in the area 20 immediately around the current measurement location Meaₐ makes it possible to directly determine the ideal focus stack starting point FSᵢ with the formula explained further above, or to at least advantageously avoid a second measurement of the focus stack at the current measurement location MEₐ.

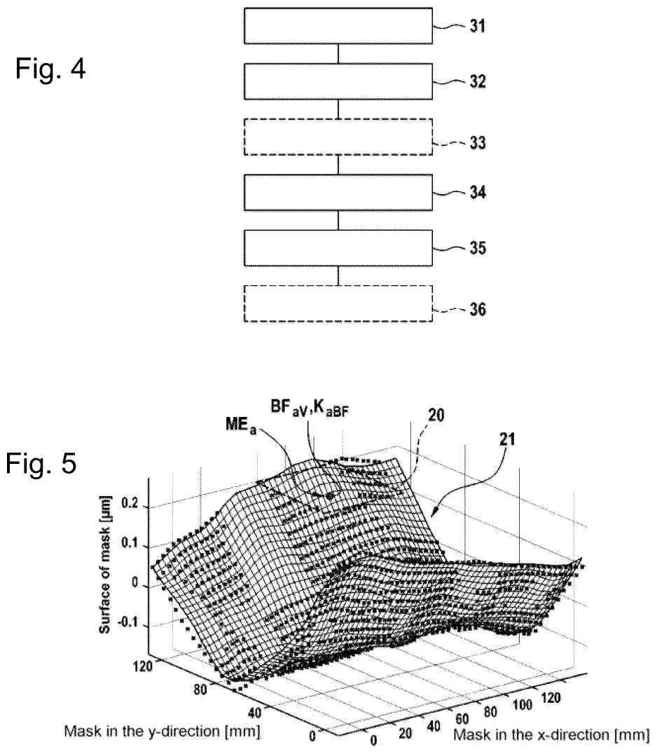

FIG. 4 describes a possible method for predicting the current best focus BFₐᵥ.

In a first method step 31, as explained in FIG. 3B, the area 20 and thus the measurement locations ME₁, ME₂ relevant to the prediction of the current best focus BFₐᵥ are determined.

In a second method step 32 known from the prior art, corrections, which can be identified on the basis of air pressure changes, are made to the determined deviations Aᵥ₁, Aᵥ₂. The air pressure is continuously recorded, as a result of which the changes based on it, in particular during the imaging by the imaging optical unit 8 (FIG. 1) of the mask inspection microscope 1, can be corrected comparatively easily.

In an optional, third method step 33, the structure class offset SK_{O} explained further above is determined for the structure elements formed in the section to be measured and is applied to the relevant measurements.

In a fourth method step 34 which is also optional, a focus information map 21 or a focus map 21 is determined, which is explained in more detail in FIG. 5.

In a fifth method step 35, the current best focus BFₐᵥ is determined, wherein this is determined either by means of the method explained further above from the previously determined static component and the correction value K_{aBF} determined on the basis of the relevant measurement locations ME₁, ME₂ within the area 20 of the current measurement location MEₐ and corresponding to the dynamic component or is determined directly from the focus information map 21 or the focus map 21 explained in more detail in FIG. 5 and determined in the previous method step 34.

In the optional method step 36, the best predicted focus BFₐᵥ is corrected with the structure class offset SK_{O}.

FIG. 5 shows a diagram with a focus information map 21 or focus map 21 determined on the basis of the relevant previous measurement locations ME₁, ME₂ in the area 20 in the vicinity of the current measurement location MEₐ.

The focus information map 21 is created on the basis of the respective deviations Aᵥ₁, Aᵥ₂ of the measurement locations ME₁, ME₂ used for the map, which are represented in FIG. 5 by small crosses as support points of the focus information map 21. A thin plate spline is used for creation, as already explained.

The correction value K_{aBF}, corresponding to the dynamic component, for the current measurement location MEₐ can be read from the focus information map 21 directly on the basis of the x,y coordinates of the current measurement location MEₐ. This has the advantage that the static component known in advance for each measurement location ME₁, ME₂, MEₐ can be added to the correction value K_{aBF} determined from the focus information map 21 and corresponding to the dynamic component in order to determine the best predicted focus at the current measurement location MEₐ. In the case of a normalized focus information map 21, i.e. a focus information map 21 independent of structure classes, the structure class offset SK_{O} can also be added to the static component in addition to the correction value K_{aBF}. The use of the deviations Aᵥ₁, Aᵥ₂ has the advantage that the difference between the deviations Aᵥ₁, Aᵥ₂ is comparatively small compared to the differences between the best focuses BF_{vMx}. This results in advantageous higher accuracy in the thin plate spline. Due to the method of operation of the thin plate spline, a sufficiently accurate prediction of the deviations is only possible from a number of seven or more measurement locations or items of focus information from different measurement locations ME₁, ME₂. The use of deviations Aᵥ₁, Aᵥ₂ of measurement locations ME₁, ME₂ with a predefined maximum distance from the current measurement location MEₐ, as explained further above, already results according to embodiments of the method, even without the use of a focus information map 21, in a significant improvement compared to the prior art from the second measurement.

Alternatively, a focus map 21 can be determined on the basis of the static components and the dynamic components Aᵥ₁, Aᵥ₂ of the previous measurement locations ME₁, ME₂, i.e. a map of the best focuses BF_{vMx}. In the example shown, the known measured best focuses BF_{vMx} are connected to each other to form the focus map 21 using a thin plate spline. The best predicted focus BFₐᵥ is also read directly from the focus map 21 on the basis of the x,y coordinates of the current measurement location MEₐ and must only, if it is a normalized, i.e. structure-independent, focus map 21, also be corrected with the structure class offset SK_{O} of the structure of the current measurement location MEₐ.

The temporal order of the measurement locations ME₁, ME₂, ME₃, MEₐ illustrated in FIG. 3B can be defined according to embodiments of the method, as explained further above, in such a way that the number of measurements until a sufficient number of measurement locations ME₁, ME₂, ME₃ are in the defined area 20 is minimized.

In a first step, the second measurement location is already selected, if possible, such that the first measurement location ME₁ is located within the area 20 defined for this second, current measurement location MEₐ. Furthermore, the temporal order in which the measurement locations ME₂, ME₃ are approached is defined in such a way that the number of measurement locations ME₁, ME₂, ME₃ in the area 20 of the current measurement location MEₐ is at a maximum.

As a result of the method, a significant improvement in the accuracy of the predicted best focus compared to the prior art can be ensured already from the second measurement and the number of measurements until the use of the focus information map 21 or the focus map 21 can be minimized.

After the determination of the focus information map 21 or focus map 21, the current best focus BFₐᵥ of the current measurement MEₐ can be easily read or determined therefrom via the measurement position (x,y coordinates).

As an alternative to the thin plate spline method explained above, the focus information map 21 or the focus map 21 can also be determined by means of one of the following methods: Inverse distance weighted (IDW) method, modified Shepard method, ordinary or universal kriging, and other spline methods.

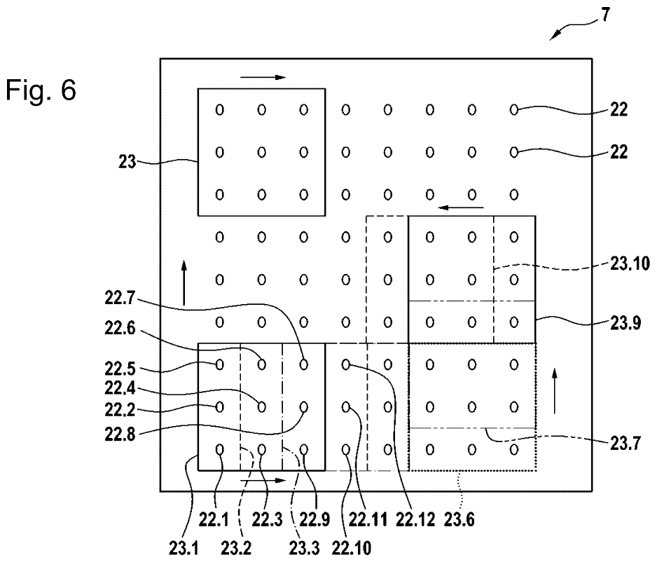

FIG. 6 shows a schematic illustration of a detail of the method, which illustrates a possible travel regime for approaching the individual measurement locations 22 on the mask 7. The travel regime is optimized for the use of a least squares fit (LSQ fit) method.

The travel regime comprises a base cell 23 with a predefined number of measurement locations 22.1-22.9. In the case of the embodiment shown in FIG. 6, the base cell comprises nine measurement locations 22.1-22.9. The size of the base cell 23 depends on the stability of the machine and/or the machine environment. As explained further above, the base cell 23 can theoretically also include the entire mask 7.

In the embodiment shown in FIG. 6, the measurement of the mask 7 starts in the lower left corner, and so the first position of the base cell 23.1 is also located there, which is illustrated in FIG. 6 with a solid line. The suffix of the reference numbers stands for the position of the size of the base cell 23 that remains constant in the embodiment.

Within the base cell 23.1, the order in which the measurement locations 22.1-22.9 belonging to the base cell 23.1 are approached is indicated by the suffix of the reference signs of the measurement locations 22.1-22.9. The measurement location with the reference sign 22.1 is approached first, followed by the measurement location with the reference sign 22.2, etc.

Already after three approached measurement locations 22.1-22.3, it is possible to determine a plane in x,y,z which is designed, for example, as a focus information map (21) or the focus map (21). The three measurement locations 22.1-22.3 used both meet the requirement for a minimum time period between the measurements (ME_{I}) already carried out and the current measurement (MEₐ) still pending and are located in an optimized small area 21 around the current measurement location (MEₐ). The quality of the LSQ fit increases with the number of measurements and is updated after each further measurement location. The focus information map (21) or the focus map (21), which is constantly updated in this way, is used to predict the best focus (BF_{IV}) of the current measurement location.

If all nine measurement locations 22.1-22.9 of the base cell 23.1 have been approached and the predefined measurements have been carried out at the measurement location 22.1-22.9, the base cell 23.1 is moved one column to the right and is now at a second position. In FIG. 6, the moved base cell 23.2 is illustrated as a dashed line.

In the embodiment illustrated in FIG. 6, the new base cell 22.2 contains the measurement locations 22.3, 22.4, 22.6-22.9 already measured in the base cell 22.1, as well as three measurement locations 22.10, 22.11, 22.12 which have not yet been measured. After these measurement locations 22.10, 22.11, 22.12 have also been measured, the base cell 23.2 is again moved further to the right and towards the base cell 23.3, which is illustrated in FIG. 6 with dot-dashed lines. The base cell 23.3 comprises, as explained, three further measurement locations which have not yet been measured and have no reference signs in FIG. 6.

The base cell 23.6, which is illustrated in FIG. 6 with dotted lines, cannot be moved further to the right, and so, after measuring all measurement locations, the base cell 23.6 is moved up by one line.

After three movements upwards, the base cell 23.9 is moved horizontally to the left and towards the base cell 23.10. The base cell 23.10 is therefore moved in a meandering manner over the mask 7, in which case, with each movement, three new measurement locations are added to the moved base cell and three measurement locations that have already been measured, ideally those with the longest time period between the pending measurement of the current measurement location and the measurements already carried out at the measurement locations, are removed from the base cell.

This ensures that both the area (20) and the time period needed to determine the focus information (Aᵥ₁,Aᵥ₂,BF_{vM1},BF_{vM2}) to be taken into account are complied with almost automatically by means of the travel regime, as explained in FIG. 3B.

For other methods of determining the focus information Aᵥ₁, Aᵥ₂, BF_{vM1}, BF_{vM2}) to be taken into account, for example regression methods or machine learning methods or other methods, the number of measurement locations 22, the shape of the base cell 23, the order when approaching the measurement locations 22 and/or the movement of the base cell 23 over the mask 7 may differ from those explained in FIG. 6. In the event of an irregular arrangement of the measurement locations 22, the order in which the measurement locations are approached must be determined by means of optimization methods, and so the base cell always contains at least three (or more) already measured measurement locations from step to step. The optimization criterion is not the shortest travel distance, but always the base cell that is expediently occupied for determining the next current best focus (BF_{IV}).

Analytical steps of embodiments of the methods disclosed herein can be implemented, at least in part, in digital electronic circuitry, or in computer hardware, firmware, or in combinations of these. For example, the features can be implemented in a computer program product tangibly embodied in an information carrier, e.g., in a machine-readable storage device, for execution by a programmable processor; and features can be performed by a programmable processor executing a program of instructions to perform functions of the described implementations by operating on input data and generating output. The described features can be implemented in one or more computer programs that are executable on a programmable system including at least one programmable processor, such as multiple processors, coupled to receive data and instructions from, and to transmit data and instructions to, a data storage system, at least one input device, and at least one output device. A computer program includes a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors one of multiple processors of any kind of computer. Generally, a processor will receive instructions and data from a read-only memory or a random access memory or both. Computers include a processor for executing instructions and one or more memories for storing instructions and data. Generally, a computer will also include, or be operatively coupled to communicate with, one or more mass storage devices for storing data files; such devices include magnetic disks, such as internal hard disks and removable disks; solid-state disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits). The features can implemented in a single process or distributed among multiple processors at one or many locations. For example, the features can employ cloud technology for data transfer, storage, and/or analysis.

Other aspects, embodiments, and features are within the scope of the following claims.

### LIST OF REFERENCE SIGNS

1 Mask inspection microscope
2 Recording device, CCD camera
3 Light source for reflection
4 Light source for transmitted light
5 Condenser
6 Object stage
7 Mask
8 Imaging optical unit
9 Semi-transparent mirror
10 Tube
11 Controller
12 Measurement light for reflection
13 Measurement light for transmitted light
14 Illumination unit
15 Focal plane
16 Mask surface
20 Area
21 Map of best focus
22, 22.1-22.12 Measurement location; measurement location measurement order
23, 23.1-23.10 Base cell of a fit model/position of the base cell during the measurement
O_{Ms} Determined mask surface including static deviation
F_{b},F_{b0},F_{bv} Best focus, best focus in the first measurement at the measurement location, predicted best focus
FS Focus stack starting point (general)
FSᵢ Ideal focus stack starting point
FSᵣ Real focus stack starting point
AB₁-AB₇ Imaging points of a focus stack
Kₘ Maximum contrast
BF_{IV} Prediction of best focus of the preceding measurement
BF_{vV1}-BF_{vV3}, Prediction of best focus of the previous measurement
BF_{IM} Measured best focus of the preceding measurement
BF_{vM1}-BF_{vM3} Measured best focus of previous measurements
BF_{asA} Best focus of the current measurement incl. static component
BFₐᵥ Prediction of current best focus
A_{I},Aᵥ₁, Aᵥ₂ Deviation of FS_{IV}-FS_{IM} or FS_{vVx}-FS_{vMx}
ATₛ Static component of predicted best focus
K_{aFS} Correction value for the best focus of the current measurement
MEₐ Current measurement/measurement location
ME_{I} Preceding measurement
ME₁, ME₂, ME₃ Previous measurement locations

What is claimed is:

1. A method for predicting a best focus for focusing at a current measurement location of at least one section of an object in a semiconductor technology apparatus,
characterized in that
a current predicted best focus is determined at least on the basis of focus information from at least one previous measurement location in the vicinity of the current measurement location (.

2. The method of claim 1,
characterized in that
an area around the current measurement location is defined for determining the at least one previous measurement location for determining the focus information to be taken into account.

3. The method of claim 1,
characterized in that
a time period, which may be at most between the time of the at least one measurement at a previous measurement location and the time of measurement at the current measurement location, is defined, so that the measurement at the previous measurement location can be used to determine the focus information to be taken into account.

4. The method of claim 1,
characterized in that
a travel regime for approaching the measurement locations is defined such that within the time period at least one measurement at a previous measurement location for determining the best focus based on focus information at the current measurement location is always within a defined area.

5. The method of claim 1,
characterized in that
the focus information comprises deviations between a best focus predicted for a previous measurement location and a best focus determined after focusing at the same measurement location.

6. The method of claim 1,
characterized in that
the current predicted best focus is determined based on predictable deviations and/or the focus information determined at previous measurement locations.

7. The method of claim 1,
characterized in that
a structure class is determined for a structure element formed in the section to be measured.

8. The method of claim 7,
characterized in that
a structure class offset is determined on the basis of the structure class.

9. The method of claim 8,
characterized in that
the structure class offset in the case of known structures is determined on the basis of simulation models.

10. The method of claim 8,
characterized in that
the current predicted best focus or the at least one item of focus information for the measurement at the current measurement location is corrected with the structure class offset of the previous measurement location and the current measurement location.

11. The method of claim 8,
characterized in that
the focus information and the best focuses are normalized with the structure class offset.

12. The method of claim 8,
characterized in that
a focus information map and/or a focus map is/are determined from the focus information from the previous measurements.

13. The method of claim 12,
characterized in that
the focus information map or the focus map is determined for the defined area.

14. The method of claim 12,
characterized in that
an interpolation method and/or a regression method and/or a machine learning method is/are used to determine the focus information map or the focus map.

15. The method of claim 14,
characterized in that
a thin plate spline is used to determine the focus information map or the focus map.

16. The method of claim 14,
characterized in that
an LSQ fit is used to determine the focus information map or the focus map.

17. The method of claim 14,
characterized in that
a Bayesian model is used to determine the focus information map or the focus map.

18. The method of claim 12,
characterized in that
the current predicted best focus is determined on the basis of the focus information map or the focus map.

19. The method of claim 8,
characterized in that
the current predicted best focus for the current measurement is corrected with the structure class offset.

20. The method of claim 8,
characterized in that
in the case of unknown structures to be measured, a probability of how the structure to be measured is formed is determined based on the previous structures and the knowledge of a measurement strategy.

21. The method of claim 20,
characterized in that
a limit value for the probability is determined.

22. The method of claim 21,
characterized in that
the structure class offset for the unknown structure to be measured is applied for a probability above the limit value.

23. The method of claim 12,
characterized in that
the travel regime for approaching the measurement locations is defined in such a way that the determination of the focus information map or the focus map is optimized in time and/or space.

24. The method of claim 23,
characterized in that
the travel regime uses a base cell.

25. The method of claim 24,
characterized in that
the number of measurement locations in the base cell is defined on the basis of the stability of the machine and/or the measurement environment.

26. The method of claim 24,
characterized in that
the base cell is moved after approaching all the measurement locations belonging to the base cell.

27. The method of claim 26,
characterized in that
the base cell is moved in such a way that the base cell always comprises a sufficient number of measurement locations for determining the focus information map or the focus map.

28. The method of claim 1,
characterized in that
the semiconductor technology apparatus is in the form of a registration apparatus.
